(19) United States
(12) Patent Application Publication
(10) Pub. No.: US 2003/0139006 A1
(43) Pub. Date: Jul. 24, 2003

(54) Method for producing capacitor structures

(76) Inventors: Hartner Walter, Glen Allen, VA (US); Rainer Florian Schnabel, Hohenkirchen (DE); Guenther Schindler, Muenchen (DE)

Correspondence Address: SCHIFF HARDIN & WAITE, 6600 SEARS TOWER, 233 S WACKER DR, CHICAGO, IL, 60606-6473, US

(21) Appl. No.: 10/258,927

(22) PCT Filed: Apr. 27, 2001
(86) PCT No.: PCT/EP01/04786

(30) Foreign Application Priority Data
Apr. 28, 2000 (DE) 100226558

(51) Int. Cl. H01L 21/8242; H01L 21/20

(52) U.S. Cl. 438/240; 438/396

(57) ABSTRACT

The invention relates to a method for producing at least one capacitor structure, comprising the following steps: providing a substrate, producing a first electrode on said substrate, producing a mask, whereby the first electrode is disposed in an opening of said mask, and applying at least one dielectric layer and at least one conductive layer for a second eletrode. The surface of the part of the conductive layer that is applied in the opening of the mask is substantially disposed below the surface of the mask. The conductive layer and the dielectric layer are structured by polishing so that a capacitor structure is produced.

The present invention relates to a method for producing capacitor structures. The present invention relates, in particular, to a method for producing ferroelectric capacitor structures or capacitor structures whose dielectric has a high dielectric constant.

In order that the charge stored in a storage capacitor of a memory cell may be read out in a reproducible manner, the capacitance of the storage capacitor should have at least a value of about 30 fF. At the same time, the lateral extent of the capacitor must be continually reduced in size in order to be able to achieve an increase in the storage density. These contrasting requirements of the capacitor of the memory cells lead to ever more complex structuring of the capacitor (“trench capacitors”, “stacked capacitors”, “crown-shaped capacitors”) in order to be able to provide a sufficient capacitor area despite the lateral extent of the capacitor becoming smaller. Accordingly, the production of the capacitor becomes more and more complicated and thus more and more expensive. Another possibility for ensuring that the capacitor has a sufficient capacitance is to use different materials for the dielectric layer between the capacitor electrodes. Recently, therefore, the use of conventional silicon oxide/silicon nitride has been replaced by the use of new materials, in particular high-ε paraelectrics and ferroelectrics, between the capacitor electrodes of a memory cell. These new materials have a distinctly higher relative permittivity (>20) and the conventional silicon oxide/silicon nitride (<8). This means that given the same capacitance, the lateral extent of the memory cell and the requisite capacitor area and thus the requisite complexity of the structuring of the capacitor can be distinctly reduced by the use of these materials. Barium strontium titanate (BST, (Ba,Sr)TiO₃), lead zirconate titanate (PZT, Pb(Zr,Ti)O₃) and/or lanthanum-doped lead zirconate titanate or strontium bismuth tantalate (SBT, SrBi₂Ta₂O₉) are used, for example.

In addition to conventional DRAM memory modules, in the future ferroelectric memory arrangements, so-called FRAMs, will also play an important part. Compared with conventional memory arrangements, such as, for example, DRAMs and SRAMs, ferroelectric memory arrangements have the advantage that the stored information is not lost, but rather remains stored, even in the event of interruption of the voltage or current supply. This nonvolatility of ferroelectric memory arrangements is based on the fact that, in the case of ferroelectric materials, the polarization impressed by an external electric field is also essentially maintained after the external electric field has been switched off. The new materials already mentioned, such as lead zirconate titanate (PZT, Pb(Zr,Ti)O₃) and/or lanthanum-doped lead zirconate titanate or strontium bismuth tantalate (SBT, SrBi₂Ta₂O₉), are used for ferroelectric memory arrangements as well.

Unfortunately, the high-ε paraelectrics and ferroelectrics can only be structured with difficulty by means of conventional etching processes. If these material are used for the production of dielectric layers for storage capacitors, then these materials additionally necessitate new electrode materials which are compatible with the process steps for depositing the new dielectrics. Thus, e.g. the dielectrics are deposited at high temperatures which would oxidize the conventional electrode materials, e.g. doped polysilicon, already present on the substrate and thus render them non-conductive. This last would lead to the failure of the memory cell.

Owing to their good oxidation resistance and/or the formation of electrically conductive oxides, 4d and 5d transition metals, in particular noble metals such as Ru, Rh, Pd and Os, and in particular Pt, Ir and IrO₂, are promising candidates that might replace doped silicon/polysilicon as electrode material.

Unfortunately, it has been found that the abovementioned electrode materials newly used in integrated circuits belong to a class of materials which can only be structured with difficulty. By way of example, these materials belong to the materials which, chemically, can be etched only with difficulty or not at all and in which the etching removal, even when using “reactive” gases, is based predominantly or almost exclusively on the physical component of the etching. The consequence of this is that the etching edges are not steep and very small structures can only be produced with difficulty. Moreover, redepositions that are difficult to remove are often observed at the etching edges.

An alternative method for structuring layers can be carried out with the aid of the CMP process step (Chemical-Mechanical Polishing, e.g. U.S. Pat. No. 5,976,928). In this method, the structure is prescribed by a mask made of a material that can easily be structured photolithographically, e.g. silicon oxide or silicon nitride. Coating ensues with the material to be structured, with a layer thickness which corresponds at least to the thickness of the mask. Afterward, the material to be structured is removed down to the mask in a CMP step. This yields a planar surface on which the material to be structured has assumed the structure of the open regions of the mask.

The removal by means of the CMP process step is effected by polishing using a “pad” which moves with defined pressure and relative speed over the substrate. An important element of the CMP process is the use of a polishing agent, also called “slurry”, between substrate and pad, which must be co-ordinated with the material to be removed. The slurry comprises a solution containing both abrasive particles of specific size for the mechanical removal and chemical components which react with the layer surface and can accelerate the removal.

In the case of the new electrode materials, the chemical component of a CMP step makes little contribution to the removal on account of the inertness of the materials. The removal is primarily effected by the mechanical action of the abrasive particles of the slurry. Accordingly, these materials can only be removed from the substrate surface at a low removal rate. Furthermore, there is an increase in the risk of scratches being formed, which can destroy the functionality of a layer construction. On the other hand, experiments with highly aggressive chemical components in the slurry have not led to the desired results.

A further limitation of the standard CMP process step for structuring layers is that conformal coating is not possible if the substrate has a structure in the vertical direction in the open mask regions. However, this is exactly what is standard in large scale integrated memory components, since the bottom electrodes, in order to obtain a maximum capacitance for a minimum lateral extent, are structured in three dimensions.

The structuring of layers by the customary CMP method therefore has a number of difficulties with regard to the production of large scale integrated memory components: a) as a result of the possibly high proportion of mechanical abrasion during a conventional CMP step, which is necessary for example in the case of the chemically inert materials, the surface may at the end have scratches which damage a thin layer, in particular a dielectric, and can thus destroy a capacitor; b) the surface of the layer to be structured can be irreversibly contaminated by the slurry and the abrasion in the case of a conventional CMP step; and c) conventional CMP structuring methods cannot produce a structured layer that is conformal with respect to the substrate, particularly if the substrate has vertical structures in the region of the mask openings.

The document U.S. Pat. No. 5,976,928 discloses a method for producing ferroelectric storage capacitors in which the bottom electrode, the ferroelectric layer and the top electrode are structured simultaneously by means of a single CMP step. To that end, by way of example, a first noble metal layer, a ferroelectric layer and a second noble metal layer are deposited on an insulating layer, which has depressions, and all regions of these layers outside the depressions are removed by means of a single CMP step. On account of the CMP step, however, electrically conductive connections between the two noble metal layers can form at the upper edges of the depressions, and thus short-circuit the two electrodes of the capacitor, which leads to the failure of the storage capacitor.

EP 0 771 022 A2 discloses a method for producing a capacitor for an analogue circuit, in which the top electrode of the capacitor is produced by means of so-called damascene technology. In this case, an opening is produced in an insulation layer applied to the bottom electrode and the capacitor dielectric, the capacitor dielectric being uncovered in said opening. This opening is then completely filled with the material of the top electrode and polished back as far as the surface of the insulation layer. JP 7-022 518 A describes a method for producing a storage capacitor, in which the bottom and top electrodes are in each case produced by separate damascene technologies. The intervening capacitor dielectric is deposited without structuring.

The present invention is based on the object of specifying a method for producing capacitor structures which reduces or completely avoids the disadvantages of the conventional methods. In particular the object of the present invention is to specify a method for producing capacitor structures which enables ferroelectric capacitor structures or capacitor structures whose dielectric has a high dielectric constant to be produced in a cost-effective manner.

This object is achieved by the method for producing at least one capacitor structure in accordance with the independent patent claim 1. Further advantageous embodiments, refinements and aspects of the present invention emerge from the dependent patent claims, the description and the accompanying drawings.

The invention provides a method for producing at least one capacitor structure, having the following steps:

a) a substrate is provided,

b) a first electrode is produced on the substrate,

c) a mask is produced, the first electrode being arranged in an opening of the mask,

d) at least one dielectric layer and at least one conductive layer for a second electrode are applied, the surface of that part of the conductive layer which is applied in the opening of the mask essentially being arranged below the surface of the mask, and

e) the conductive layer and the dielectric layer are removed from the surface of the mask by polishing, so that a capacitor structure is produced.

The method according to the invention has the advantage that the conductive layer is structured with the aid of the mask without the residual structured region of the conductive layer, which later forms the top electrode, having come into contact with the polishing object. This is due to the fact that the mask, whose upper edge is higher than the upper edge of the layer to be structured in the opened mask regions, protects the residual regions of the conductive layer. At the same time, if appropriate, a layer profile that is conformal with respect to the substrate is preserved in the opened mask regions, which is advantageous for example for the production of storage capacitors with very thin dielectric layers.

The method according to the invention makes it possible, in particular, to structure and thus use in capacitor structures those materials which can only be structured with difficulty by conventional etching methods, in particular paraelectric and ferroelectric high-ε materials, and also noble metals and the electrically conductive oxides thereof. Furthermore, the method according to the invention makes it possible to produce capacitor structures with a very thin dielectric layer and therefore with a relatively large capacitance. Since the region of the thin dielectric layer which lies between the electrodes has no mechanical contact with the polishing object, there is no risk of this part of the layer being mechanically harmed and a short circuit forming between the two electrode layers of the capacitor.

In the method according to the invention, the first (bottom) electrode is already structured before the dielectric layer and the conductive layer for the second (top) electrode are applied. Accordingly, only the dielectric layer and the conductive layer for the second electrode are structured by the polishing. A formation of a conductive connection between the first and second electrodes by the polishing is thus precluded.

Preferably, a filling layer is applied to the conductive layer before the polishing step. With this arrangement, the conductive layer is protected against contaminants which may arise during the polishing step due to removal and due to the polishing agent itself. At the same time, the filling layer supports the mask structure against mechanical shear forces during the polishing.

Preferably, a covering layer, in particular an insulating covering layer, is applied to the substrate after the polishing process, in order to cover the open edges of the conductive layer which have remained at the edges of the masks.

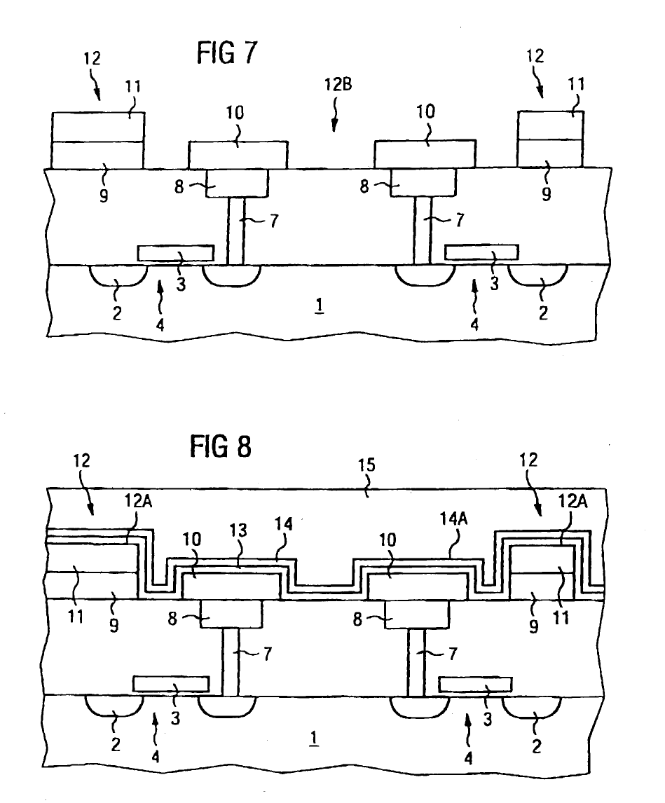

Furthermore, it is preferred if the mask comprises two or more layers. This makes it possible to ensure a highly efficient process progression over the entire production process. In the exemplary embodiment 1, e.g. the oxide layer 9 is firstly a mask for the structuring of the bottom electrodes (see FIG. 6 and FIG. 7) and later, together with the layer 11, a mask for the structuring of the layers 13 and 14 (see FIGS. 10, 11 and 12).

Furthermore, it is preferred if the material of the dielectric layer contains a dielectric having a high dielectric constant, a ferroelectric layer and/or the precursor of a ferroelectric layer. In particular, SBT, PZT or BST are preferred. Furthermore, it is preferred if the material of the conductive layer contains a noble metal, in particular Pt or Ir, or an oxide of a noble metal.

A preferred polishing process step is the CMP step (Chemical Mechanical Polishing), i.e. polishing using a polishing object (pad) and a polishing agent (slurry), which removes the layers to be structured both through chemical reactions and through mechanical grinding with slurry particles of specific size. In this case, it is preferred if a CMP step adapted to the layer to be polished is carried out for each layer to be polished.

In accordance with a preferred embodiment, the first electrode contains a noble metal, in particular Pt or Ir, or a conductive oxide of a noble metal. Furthermore, it is preferred if the first electrode is produced by a conductive layer being applied and structured by polishing. In this way, essentially the entire capacitor structure can be produced without etching methods and the associated problems. In this case, it is particularly preferred if the conductive layer for the first electrode is applied conformally to a correspondingly prepared substrate. Furthermore, it is preferred if the dielectric layer and the conductive layer for the second electrode are applied conformally. In this way, it is possible to produce capacitor structures with relatively large surfaces in a simple manner. In particular, it is preferred if the dielectric layer is applied by means of a CVD method.

Preferred materials for the mask are those which can be precisely structured by photolithographic etching methods and are compatible with the overall process, such as e.g. silicon oxide or silicon nitride.

In accordance with one embodiment, preferred filling layer materials are insulating materials, preferably those which can be removed by means of conventional CMP process steps, such as e.g. silicon oxide.

The invention is illustrated in more detail below with reference to figures of the drawing, in which:

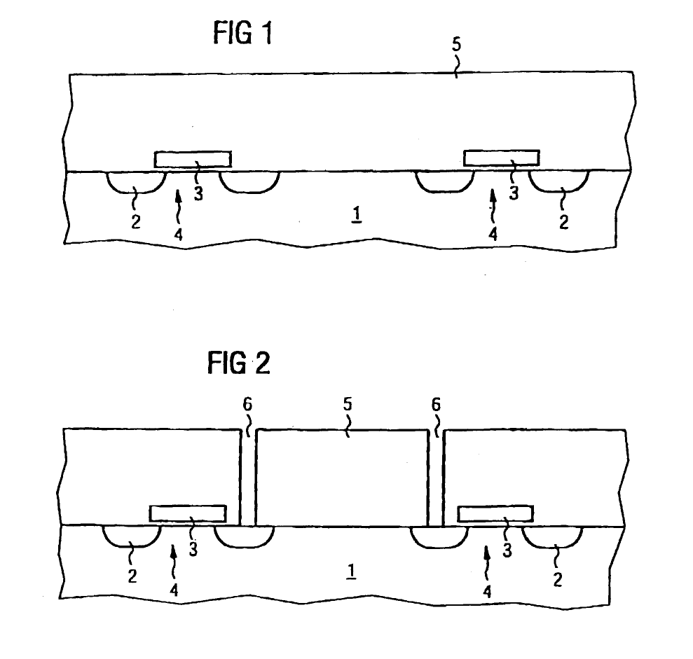

FIGS. 1-10 show a method for producing storage capacitors in accordance with a first embodiment of the present invention,

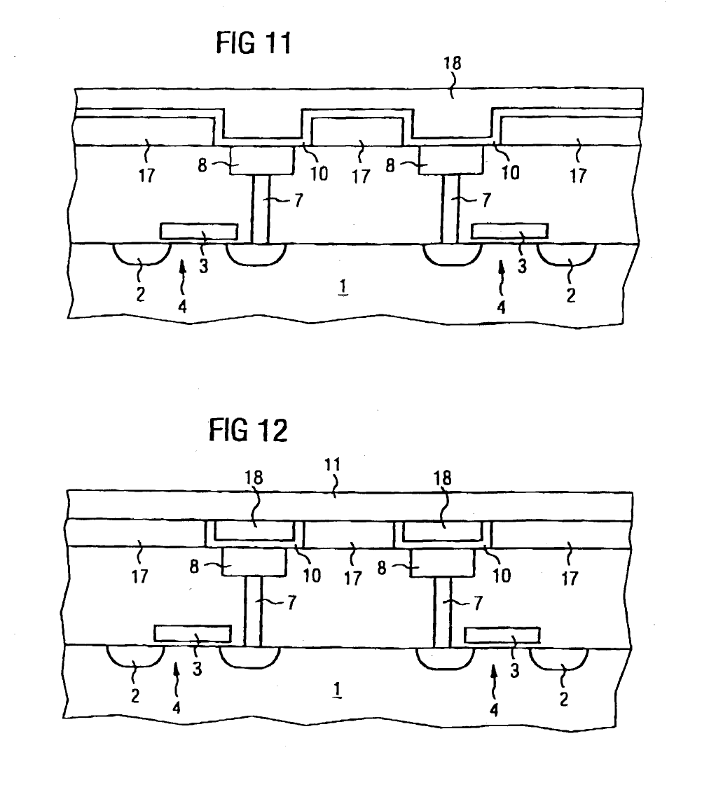

FIGS. 11-16 show a method for producing storage capacitors in accordance with a second embodiment of the present invention.

FIG. 1 shows a silicon substrate 1 with already completed transistors 4. The transistors, together with the storage capacitors yet to be produced, form the memory cells which serve for storing the binary information items. The transistors 4 each have two diffusion regions 2 arranged at the surface of the silicon substrate 1. The channel zones are arranged between the diffusion regions 2 of the transistors 4, said channel zones being isolated from the gate electrodes 3 on the surface of the silicon substrate 1 by the gate oxide. The transistors 4 are produced according to the methods known in the prior art, which are not explained in any greater detail here.

An insulating layer 5, for example an SiO₂ layer, is applied to the silicon substrate 1 with the transistors 4. It is also possible to apply a plurality of insulating layers, depending on the method used for the production of the transistors 4. The resultant structure is shown in FIG. 1.

Afterward, the contact holes 6 are produced by means of a phototechnology. These contact holes 6 produce a connection between the transistors 4 and the storage capacitors that are yet to be produced. The contact holes 6 are produced for example by anisotropic etching using fluorine-containing gases. The resultant structure is shown in FIG. 2.

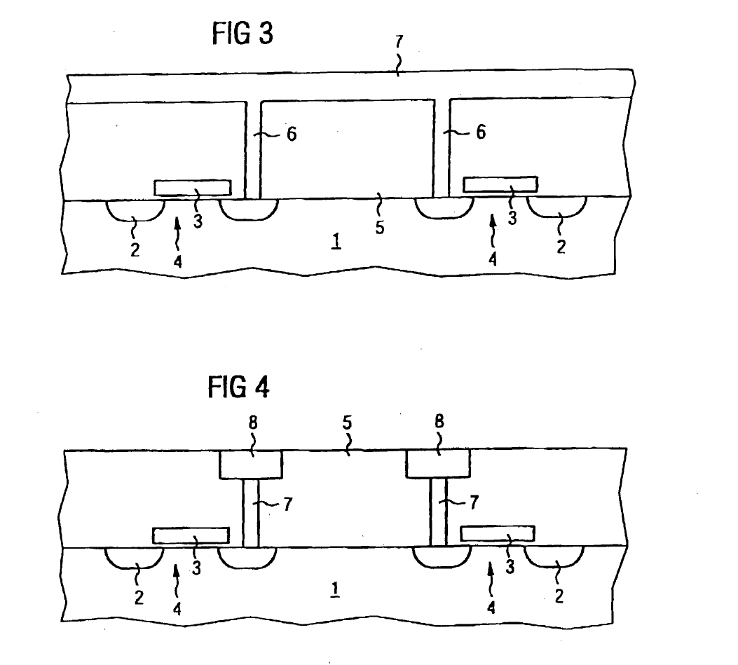

A conductive material 7, for example in situ-doped polysilicon, is subsequently applied to the structure. This can be done by means of a CVD method, for example. As a result of the application of the conductive material 7, the contact holes 6 are completely filled and a contiguous conductive layer is produced on the insulating layer 5 (FIG. 3). There then follows a CMP step, which removes the contiguous conductive layer on the surface of the insulating layer 5 and produces a planar surface.

Afterward, depressions are formed in the insulating layer 5 in an overlapping manner with respect to the contact holes 6 or only in the contact holes 6. As an alternative, depressions may also be produced in a further insulating layer (not shown) deposited onto the insulating layer 5 after the structuring of the conductive material 7. These depressions are then filled with barrier material 8, for example iridium oxide, up to a predetermined height. This is done by the barrier material 8 being deposited over the whole area and being polished back as far as the surface of the insulating layer 5 by means of a CMP step. The barrier material 8 can also be structured by anisotropic etching. Suitable CMP methods are described for example in the German patent application bearing the internal file reference GR 00 P 4087 DE and entitled “Polierflüssigkeit and Verfahren zur Strukturierung von Metalloxiden” [“polishing fluid and method for structuring metal oxides”], which was filed on the same date and to which reference is hereby made. The resultant structure is shown in FIG. 4.

This concludes the first step a) of the method according to the invention, i.e. a substrate on which a capacitor structure is subsequently produced has been provided.

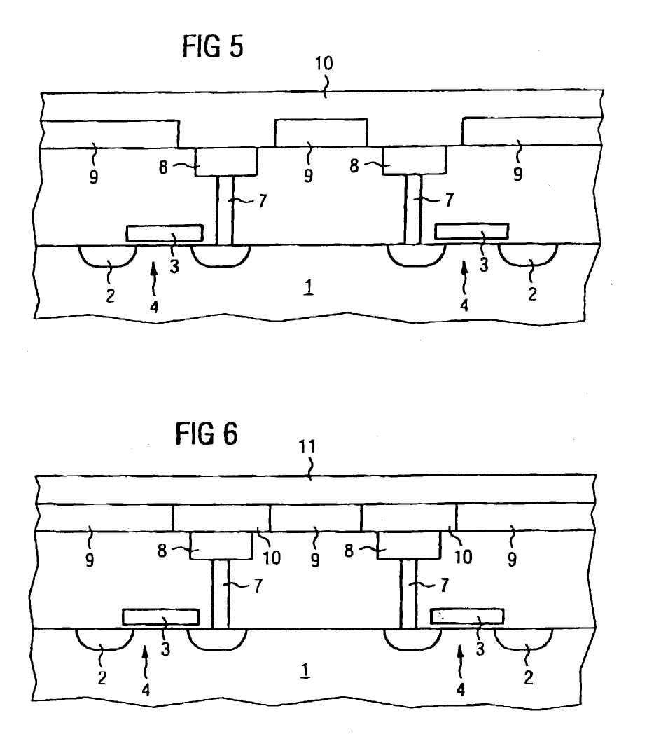

Afterward, a mask layer made of insulating material, e.g. made of silicon oxide, is applied and structured by means of a photolithographic step in such a way that it is opened in the region around the contact holes. The opened regions of the mask 9 define the geometry of the bottom electrodes. A conductive layer 10, for example a Pt layer, is then deposited onto the silicon oxide mask 9. In this case, the thickness of the conductive layer is chosen such that the openings in the silicon oxide mask 9 are completely filled. The resultant structure is shown in FIG. 5.

In a subsequent CMP step, the contiguous Pt layer 10 is removed on the surface of the silicon oxide mask 9 and a planar surface is produced. This also concludes the second step b) of the method according to the invention, i.e. a first electrode has been produced on the substrate.

For the subsequent structuring of the storage dielectric and of the top electrode, a further silicon oxide layer 11 is applied (FIG. 6). Afterward, the silicon oxide layer 11 and the silicon oxide mask 9 that has still remained are structured for the purpose of producing the mask 12 by means of phototechnology. In this case, the structuring of the silicon oxide layer 11 and of the silicon oxide mask 9 that has still remained is designed such that the bottom electrodes project in a relief-like manner in the openings 12B of the mask 12. This concludes the step c) of the method according to the invention. The three-dimensional shaping of the bottom electrode enlarges the surface of the electrode, which results in an increase in the capacitance of the storage capacitors. The resultant structure is shown in FIG. 7.

The material for a ferroelectric layer 13, for example for a layer made of strontium bismuth tantalate (SBT), is deposited. Such an SBT layer is deposited onto the substrate with the electrodes 10 and the mask 12 with the aid of a CVD process. The CVD process is carried out at a substrate temperature of 385° C. and a chamber pressure of about 1200 Pa. The oxygen proportion in the gas mixture is 60%. In this case, the SBT film is deposited as an amorphous film. Accordingly, the SBT film still exhibits essentially no ferroelectric properties. Afterward, the deposited amorphous SBT is subjected to heat treatment at a temperature of between 600 and 750° C. for 10 to 30 min in an oxygen atmosphere, thereby producing the ferroelectric properties of the SBT.

A second conductive layer 14, in this case again a Pt layer, is deposited. The deposition steps are carried out by means of a technology which corresponds to the prior art. The layers 13 and 14 lying one above the other are deposited conformally with respect to the substrate and the mask 12 and they are thin enough that the surface 14A of that part of the layers 13 and 14 to be structured which is applied in the opening 12B of the mask 12 is essentially arranged below the surface 12A of the mask 12. This concludes the step d) of the method according to the invention.

In the present embodiment of the invention, the next step is application of a filling layer 15, for example made of silicon oxide. In this case, the thickness of said filling layer 15 is chosen such that the mask openings that have remained are completely filled. The resultant structure is shown in FIG. 8.

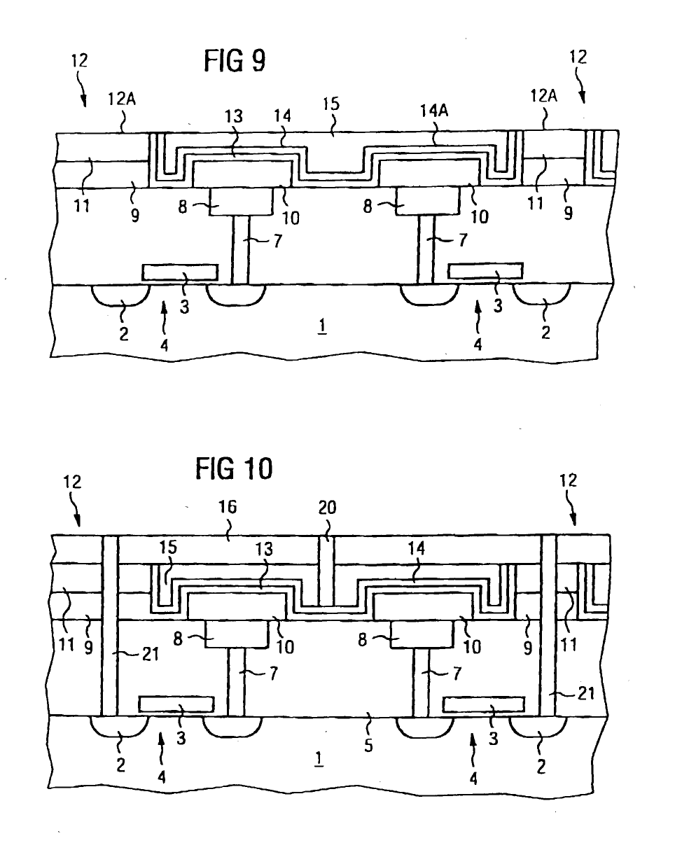

There follow three CMP process steps each adapted to the material to be removed, a first CMP step removing the filling layer 15, a further CMP step removing that part of the Pt layer 14 which is arranged on the mask 12, and a third CMP step removing that part of the ferroelectric layer 13 which is arranged on the mask 12. Consequently, a capacitor structure with the first electrode 10, the dielectric (ferroelectric) layer 13 and the second electrode 14 has been produced in accordance with step e) of the method according to the invention. On account of the filling layer 15, the structuring is effected without the residual parts of the layers 13 and 14, which belong to the active part of the capacitor, having come into contact with pad and slurry during the CMP steps. Accordingly, residual parts of the layers 13 and 14 are protected against damage and/or contaminants. The resultant situation is shown in FIG. 9.

Only the edges of the layers 13 and 14 are still visible at the edge of the mask. In order to electrically insulate the electrode layer 14 from new interconnect planes, the conductive layer 14 is covered by an insulating covering layer 16, for example silicon oxide.

In order to make electrical contact with the top electrode 14 and the diffusion regions 2—lying below the insulating layer 5—of the transistors 4, the corresponding contact holes are then etched through the various silicon oxide layers 16, 15, 11, 9 and 5. In this case, at least one contact hole 20 ends on the top Pt electrode 14; further contact holes 21 pass through the mask 12, past the Pt-SBT layers, as far as the defusion regions 2 of the selection transistors 4. A further conductive layer is deposited, so that the contact holes are filled (FIG. 10). Afterward, the metallization planes and the passivation of the component are produced in a conventional manner.

A second embodiment of the method according to the invention is illustrated in FIGS. 11 to 16. In this case, the first steps of the method in accordance with the second embodiment of the present invention correspond to what has been explained in connection with FIGS. 1 to 4, so that a repetition can be dispensed with. As shown in FIG. 4, a substrate comprising the insulating layer 5 and the barriers 8 is provided. This concludes the first step a) of the method according to the invention. Proceeding from the substrate shown in FIG. 4, a mask 17, for example made of silicon oxide, with a predetermined thickness is applied to the substrate.

Afterward, a conductive electrode layer 10, in this case made of Pt, is deposited essentially conformally onto the substrate and the mask 17. In this case, the thickness of the Pt layer 10 is less than the thickness of the mask 17. In this case, the surface of that part of the layer 10 to be structured which is applied to the substrate is essentially arranged below the surface of the mask 17.

An insulating filling layer 18, for example silicon oxide, is applied with a thickness which suffices to fill the openings of the mask 17 and of the Pt layer 10. The resultant situation is shown in FIG. 11.

There follows a CMP process step, that part of the Pt layer 10 which is arranged on the mask 17 being removed. On account of the filling layer 18, the Pt layer 10 is structured without the residual parts of the layer 10 having come into contact with the pad or the slurry during the CMP step. Accordingly, the residual parts of the layer 10 are protected against damage and/or contaminants. This concludes the second step b) of the method according to the invention, as a result of which the first electrode has been completed, in a crown geometry.

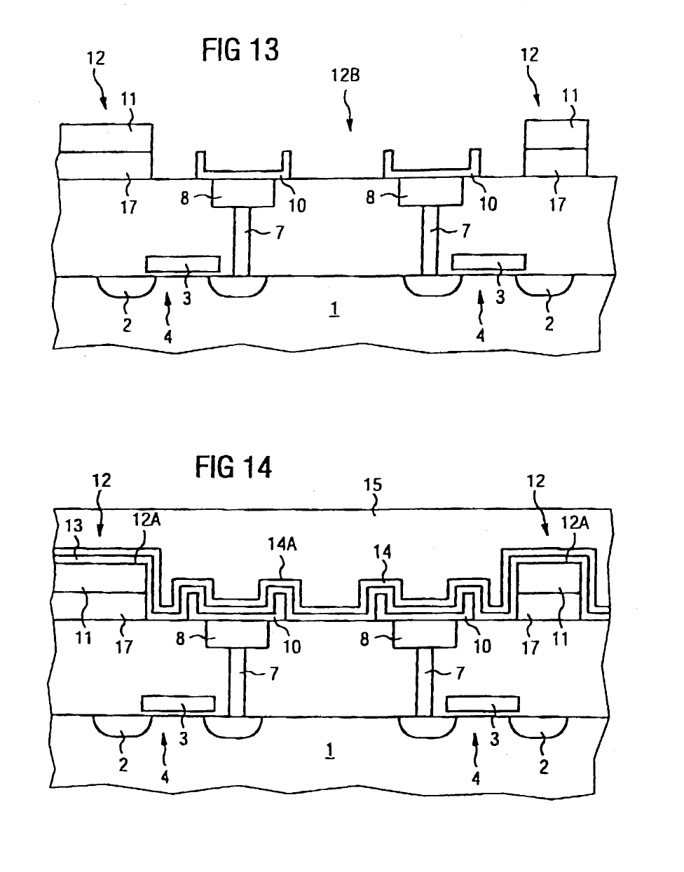

Afterward, a further silicon oxide layer 11 is then applied. The resultant situation is shown in FIG. 12. Afterward, the silicon oxide layer 11 and the silicon oxide mask 17 are structured for the purpose of producing the mask 12 by means of a phototechnology. In this case, the structuring of the silicon oxide 11 and of the silicon oxide mask 17 is again designed such that the bottom crown electrodes project in the opening 12B of the mask 12. This concludes the third step c) of the method according to the invention. The three-dimensional shaping of the bottom electrode enlarges the surface of the electrode, which results in an increase in the capacitance of the storage capacitors. The resultant structure is shown in FIG. 13.

There follow the deposition of the material for a ferroelectric layer 13, for example for a layer made of strontium bismuth tantalate (SBT), and the deposition of a second conductive layer 14, in this case again a Pt layer. The deposition steps are carried out using a technology which corresponds to the prior art. The layers 13 and 14 lying one above the other are deposited conformally with respect to the substrate and the mask 12 and they are again thin enough that the surface 14A of that part of the layers 13 and 14 to be structured which is applied to the substrate is essentially arranged below the surface 12A of the mask 12. This concludes the step d) of the method according to the invention.

As in the case of the first embodiment of the invention, the next step is the application of a filling layer 15, for example made of silicon oxide. In this case, the thickness of said filling layer 15 is chosen such that the openings of the mask that have remained are completely filled. The resultant structure is shown in FIG. 14.

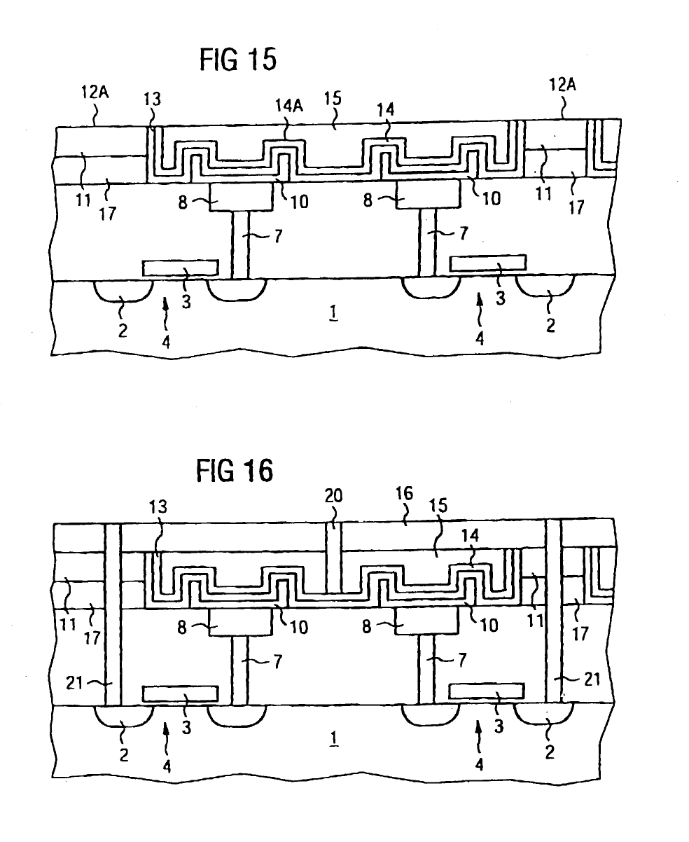

There follow three CMP process steps each adapted to the material to be removed, a first CMP step removing the filling layer 15, a further CMP step removing that part of the Pt layer 14 which is arranged on the mask 12, and a third CMP step removing that part of the ferroelectric layer 13 which is arranged on the mask 12. On account of the filling layer 15, the structuring is effected without the residual parts of the layers 13 and 14, which belong to the active part of the capacitor, having come into contact with pad and slurry during the CMP steps. Accordingly, the residual parts of the layers 13 and 14 are protected against damage and/or contaminants. Consequently, a capacitor structure with the first electrode 10, the dielectric (ferroelectric) layer 13 and the second electrode 14 has been produced in accordance with step e) of the method according to the invention. The resultant situation is shown in FIG. 15.

In order to electrically insulate the electrode layer 14 from new interconnect planes, the conductive layer 14 is covered by an insulating covering layer 16, for example silicon oxide. Afterward, in order to make electrical contact with the top electrode 14 and the diffusion regions 2—lying below the insulating layer 5—of the transistors 4, corresponding contact holes are etched through the various silicon oxide layers 16, 15, 11, 17 and 5. In this case, at least one contact hole 20 ends on the top Pt electrode 14; further contact holes 21 pass through the mask 12, past the Pt-SBT layers, as far as the defusion regions 2 of the selection transistors 4. A further conductive layer is deposited, so that the contact holes are filled (FIG. 10). Afterward, the metallization planes and the passivation of the component are produced in a conventional manner.

What is advantageous in this case is that the further contact holes 21 penetrate through the plane of the top Pt electrode 14 and of the dielectric layer 13 at the place of the mask 12 without uncovering the Pt electrode and the dielectric layer 13. These layers were removed beforehand precisely at that location on account of the method according to the invention. During the etching of the further contact holes 21, the layer of the Pt electrode 14 and the dielectric (ferroelectric layer) 13 remain embedded by the mask 17 and the SiO₂ layer 16, so that, in particular, the dielectric layer 13 cannot be damaged by the contact hole etching.

### List of Reference Symbols

1 Silicon substrate

2 Diffusion region

3 Gate electrode

4 Selection transistor

5 SiO₂ layer

6 Contact hole

7 Polysilicon layer

8 Barrier

9 Mask

10 Noble metal layer

11 SiO₂ layer

12 Mask 12A: surface of the mask

13 Ferroelectric layer

14 Noble metal layer 14A: surface of the noble metal layer

15 Filling layer

16 SiO₂ layer

17 Mask

18 Filling layer

19

20 Contact hole

21 Contact hole

1. A method for producing at least one capacitor structure, having the following steps:
a) a substrate (1) is provided,
b) at least one first electrode (10) is produced on the substrate (1),
c) a mask (12) is produced, the first electrode (10) being arranged in an opening of the mask (12),
d) at least one dielectric layer (13) and at least one conductive layer (14) for a second electrode are applied, the surface (14A) of that part of the conductive layer (14) which is applied in the opening of the mask (12) essentially being arranged below the surface (12A) of the mask (12), and
e) the conductive layer (14) and the dielectric layer (13) are removed from the surface (12A) of the mask (12) by polishing, so that a capacitor structure is produced.

2. The method as claimed in claim 1,
characterized in that a filling layer (15) is applied to the conductive layer (14) before the polishing.

3. The method as claimed in one of the preceding claims,
characterized in that a covering layer (16), in particular an insulating covering layer, is applied after the polishing.

4. The method as claimed in one of the preceding claims,
characterized in that the mask (12) comprises at least two layers (9, 11).

5. The method as claimed in one of the preceding claims,
characterized in that the material of the dielectric layer (13) contains a dielectric having a high dielectric constant, a ferroelectric and/or the precursor of a ferroelectric.

6. The method as claimed in claim 5,
characterized in that the material of the dielectric layer (13) contains SBT, PZT or BST.

7. The method as claimed in one of the preceding claims,
characterized in that the material of the conductive layer (14) contains a noble metal, in particular Pt or Ir, or an oxide of a noble metal.

8. The method as claimed in one of the preceding claims,
characterized in that the polishing is carried out as a CMP process.

9. The method as claimed in claim 8,
characterized in that a CMP step adapted to the layer to be polished is carried out for each layer to be polished.

10. The method as claimed in one of the preceding claims,
characterized in that the first electrode (10) contains a noble metal, in particular Pt or Ir, or a conductive oxide of a noble metal.

11. The method as claimed in one of the preceding claims,
characterized in that the first electrode (10) is produced by a conductive layer (10) being applied and structured by polishing.

12. The method as claimed in claim 11,
characterized in that the conductive layer (10) for the first electrode (10) is applied conformally.

13. The method as claimed in one of the preceding claims,
characterized in that the dielectric layer (13) and the conductive layer (14) for the second electrode are applied conformally.

14. The method as claimed in one of the preceding claims,
characterized in that the dielectric layer (13) is applied by a CVD method.
